(19) United States
(12) Patent Application Publication
(10) Pub. No.: US 2026/0204448 A1
(43) Pub. Date: Jul. 16, 2026

(54) SCALABLE CONFIGURATIONS FOR STACKED NUCLEAR VOLTAIC POWER SOURCES UTILIZING SPHERICAL CELLS IN CYLINDRICAL BATTERY FORM FACTOR ASSEMBLIES

(71) Applicants: Nima Golsharifi, London (GB); Mohamed Abdelbaset Ahmed, Florence (IT)

(72) Inventors: Nima Golsharifi, London (GB); Mohamed Abdelbaset Ahmed, Florence (IT)

(21) Appl. No.: 19/557,901

(22) Filed: Mar. 5, 2026

(51) Int. Cl. G21H 1/06; H05K 7/20

(52) U.S. Cl. CPC G21H 1/06; H05K 7/20

(57) ABSTRACT

A nuclear voltaic power source comprising a plurality of spherical nuclear voltaic cells arranged in disk-shaped slices stacked within cylindrical battery form factor assemblies. Each spherical cell contains at least one radioisotope, at least one converting medium (solid wide bandgap semiconductors or liquid transducers including liquid semiconductors, liquid scintillators, liquid metals, and ionic liquids), electrical contacts, and an encapsulating layer. The spherical geometry maximizes radiation solid angle capture. Multiple cells are arranged in planar disk-shaped slices connected in series or parallel, and multiple slices are stacked into cylindrical assemblies conforming to industry-standard formats including 2170, 18650, 21700, 4680, and 26650. A cylindrical external casing provides radiation shielding and standard battery terminal interfaces. The modular architecture enables customizable voltage, current, and energy capacity and direct drop-in compatibility with existing lithium-ion battery infrastructure including battery management systems and electric vehicle battery packs.

### CROSS-REFERENCE TO RELATED APPLICATIONS

This application claims priority to Singapore Patent Application No. 10202500617Q, filed 11 Mar. 2025, the disclosure of which is incorporated herein by reference in its entirety.

### FIELD OF THE INVENTION

The present invention relates to nuclear voltaic power sources and, more particularly, to scalable configurations for assembling spherical nuclear voltaic cells into disk-shaped slices and further into cylindrical battery form factor assemblies compatible with industry-standard battery formats including the 2170, 18650, 21700, and 4680 cylindrical cell standards.

The invention addresses both the individual spherical cell design incorporating multiple converting media types and the hierarchical assembly methodology for producing nuclear voltaic batteries that are drop-in compatible with existing lithium-ion battery infrastructure.

### BACKGROUND OF THE INVENTION

Nuclear voltaic cells, which convert energy from radioactive decay into electricity, are a promising alternative to conventional chemical batteries. Unlike chemical batteries that deplete over months to years, radioisotope-powered cells can operate for decades depending on the half-life of the selected isotope. Despite this potential, traditional betavoltaic and alphavoltaic cells face significant challenges with energy density per unit volume and scalability from single-cell to multi-cell configurations.

Adoption of nuclear voltaic technology has been slow due to several design complexities. First, conventional nuclear voltaic cells employ planar semiconductor geometries that capture radiation from only one or two faces, resulting in suboptimal radiation utilization. Second, existing designs lack a systematic approach to combining individual cells into larger assemblies with customizable voltage and current characteristics. Third, no existing nuclear voltaic technology has been configured to be compatible with industry-standard battery form factors, preventing drop-in replacement of chemical batteries.

The 2170 cylindrical cell format (21 mm diameter, 70 mm length) is widely adopted in electric vehicles, consumer electronics, and energy storage systems. The 18650 format (18 mm diameter, 65 mm length) is the dominant standard for portable electronics. The 4680 format (46 mm diameter, 80 mm length) represents the next generation for automotive applications. A nuclear voltaic power source configured to these standard dimensions would enable direct integration with existing battery management systems, charging infrastructure, and device form factors.

Furthermore, existing nuclear voltaic designs are typically limited to a single energy conversion mechanism, employing either solid-state semiconductor direct conversion or scintillator-mediated indirect conversion. A system that accommodates multiple converting media types within a standardized cell geometry would provide greater flexibility in optimizing performance for different radioisotope sources and application requirements.

What is needed is a modular, scalable nuclear voltaic architecture based on spherical cells that can be assembled into industry-standard cylindrical battery form factors, supporting both solid and liquid converting media, with configurable series and parallel electrical interconnection.

### SUMMARY OF THE INVENTION

The present invention provides a nuclear voltaic power source composed of multiple spherical nuclear voltaic cells arranged in disk-shaped slices that are stacked into cylindrical battery form factor assemblies. Each spherical cell contains at least one radioisotope, at least one converting medium for transforming radiation energy into electrical energy, electrical contacts for current extraction, and an encapsulating layer for containment.

The converting medium within each spherical cell may comprise solid transducers including wide bandgap semiconductors, or liquid transducers including liquid semiconductors, liquid scintillators, liquid metals, and ionic liquids. This versatility enables optimization of energy conversion for different radioisotope emission types and energies.

The spherical geometry of each cell provides uniform radiation distribution in all directions, maximizing the solid angle of radiation capture. Multiple spherical cells are arranged in a planar disk-shaped slice, with cells within each slice connected in parallel or series. Multiple slices are then stacked vertically to form a cylindrical assembly conforming to industry-standard battery form factors including, but not limited to, the 2170 (21 mm×70 mm), 18650 (18 mm×65 mm), 21700 (21 mm×70 mm), 4680 (46 mm×80 mm), and 26650 (26 mm×65 mm) standards.

An external casing encompasses the stacked slices, providing radiation shielding, structural integrity, and compatibility with standard battery terminals and connectors. The hierarchical architecture of cell, slice, and stack enables customization of voltage, current, and energy capacity by adjusting the number and arrangement of cells per slice, slices per stack, and the electrical interconnection topology.

### BRIEF DESCRIPTION OF THE DRAWINGS

FIG. 1 is a top-down cross-sectional view of a single spherical nuclear voltaic cell showing the layered construction including the encapsulating layer, outer semiconductor (or converting medium), radioisotope-containing space, inner semiconductor (or converting medium), and cylindrical electrical contacts.

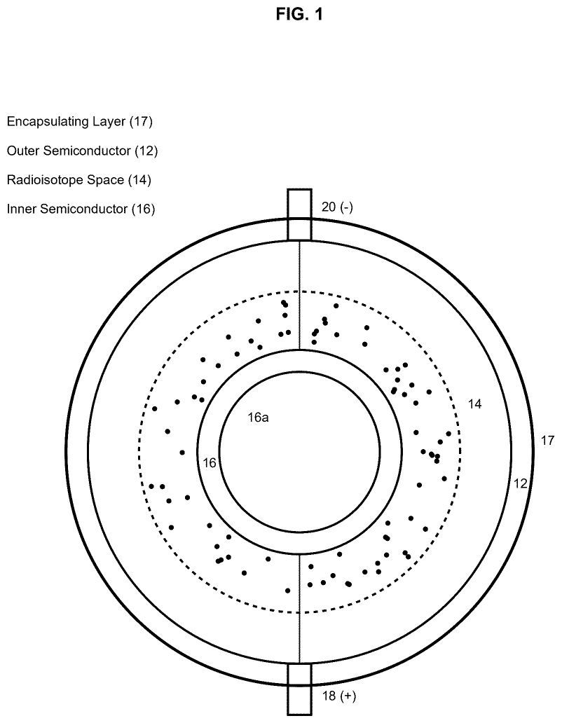

FIG. 2 is a parts reference table identifying numbered components of the spherical cell assembly.

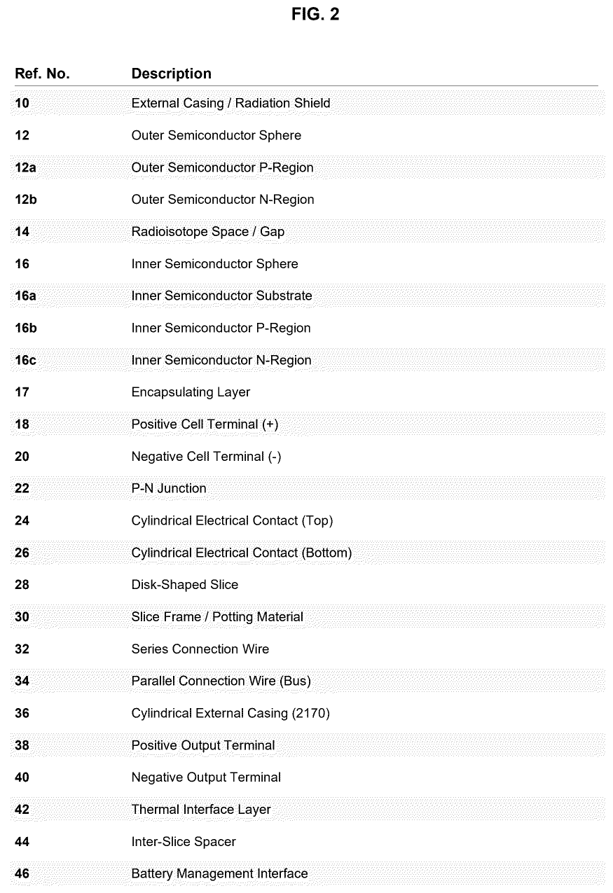

FIG. 3 is a cross-sectional isometric view of a spherical cell showing the semiconductor layers, p-n junction regions, cylindrical electrical contacts connected to positive and negative cell terminals, and the radioisotope-containing gap between inner and outer semiconductors.

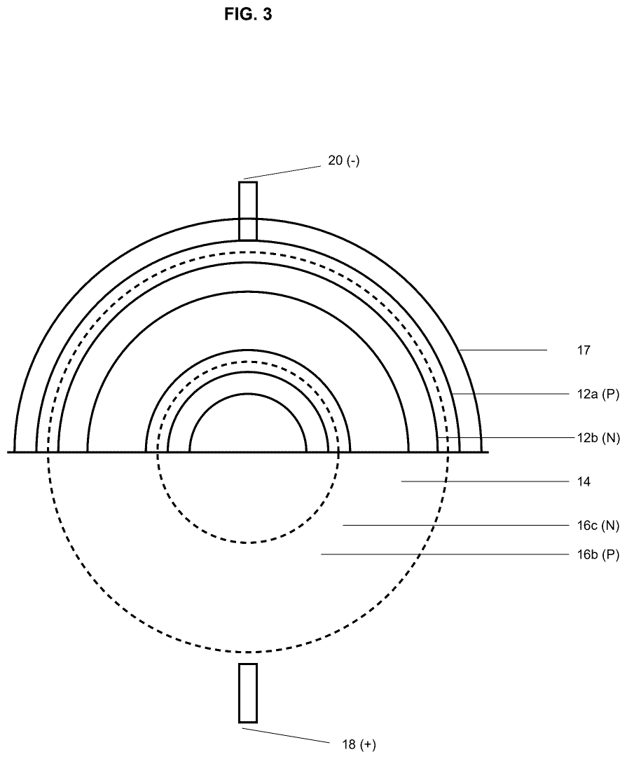

FIG. 4 is an exploded assembly view of a single spherical cell showing all layers in separated positions with assembly relationships indicated.

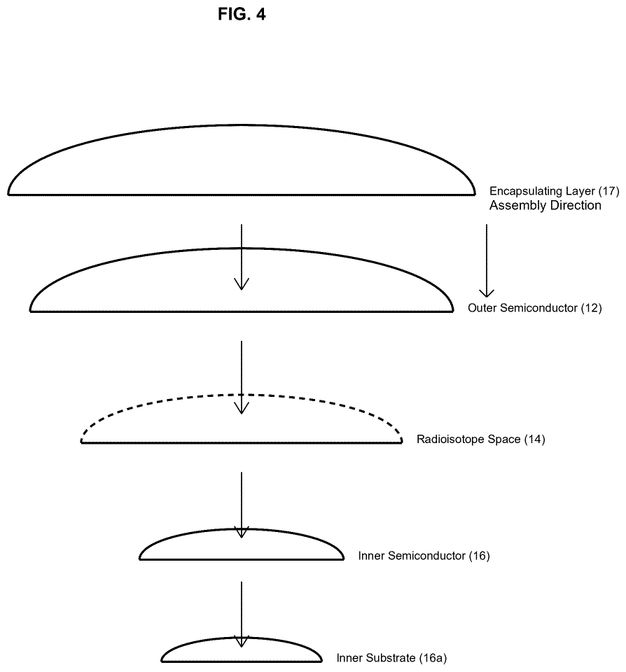

FIG. 5 is a detail view showing the electrical connection mechanism between the cylindrical contacts and the semiconductor layers, including FIG. 5.1 showing the outer semiconductor layer connections and FIG. 5.2 showing the inner semiconductor layer connections.

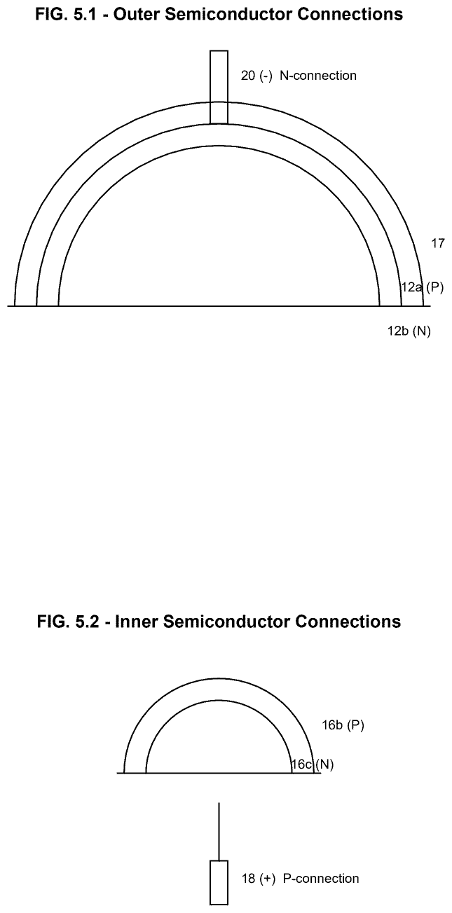

FIG. 6 is a cross-sectional detail view of the inner semiconductor showing the substrate, P-region layer, and N-region layer, each with a thickness of approximately 0.01 mm.

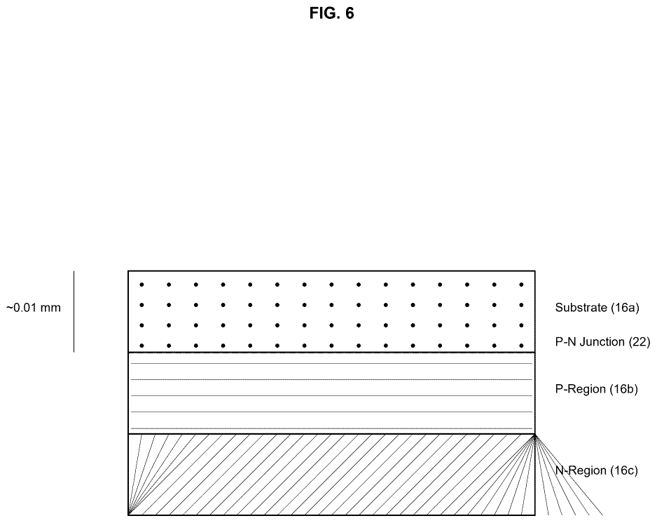

FIG. 7 is a set of detail views showing the interaction of semiconductor layers at different regions of the cell, including the positive cell terminal region and the negative cell terminal region.

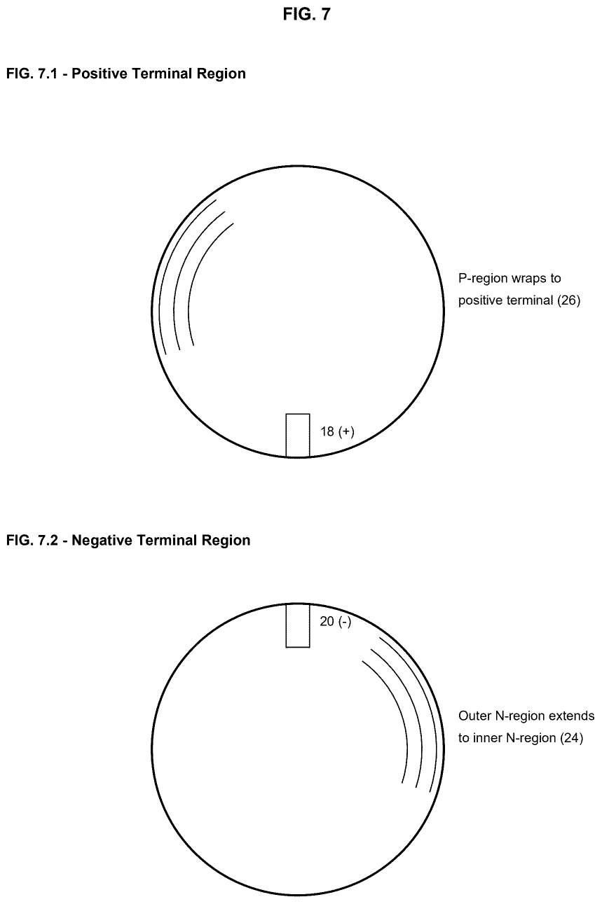

FIG. 8 is a top-down view of a disk-shaped slice assembly containing seven spherical cells in a close-packed hexagonal arrangement, showing the slice boundary and inter-cell connections.

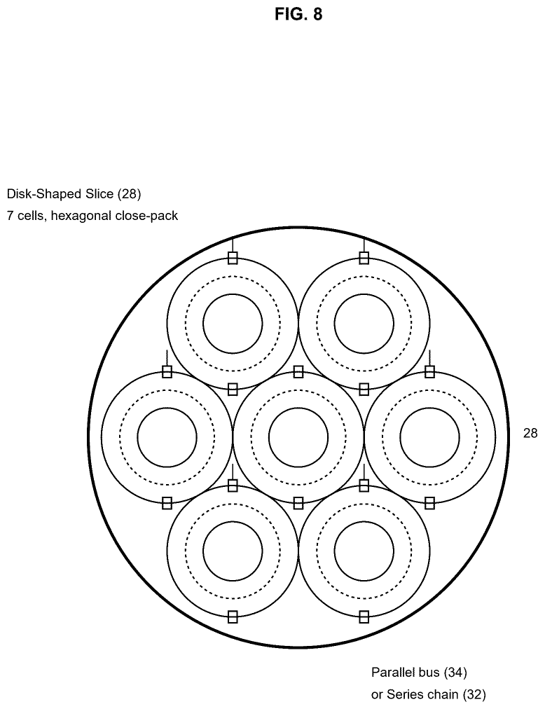

FIG. 9 is a perspective view of a cylindrical stack assembly showing multiple disk-shaped slices stacked vertically within a 2170-format external casing, with positive and negative terminals at opposite ends.

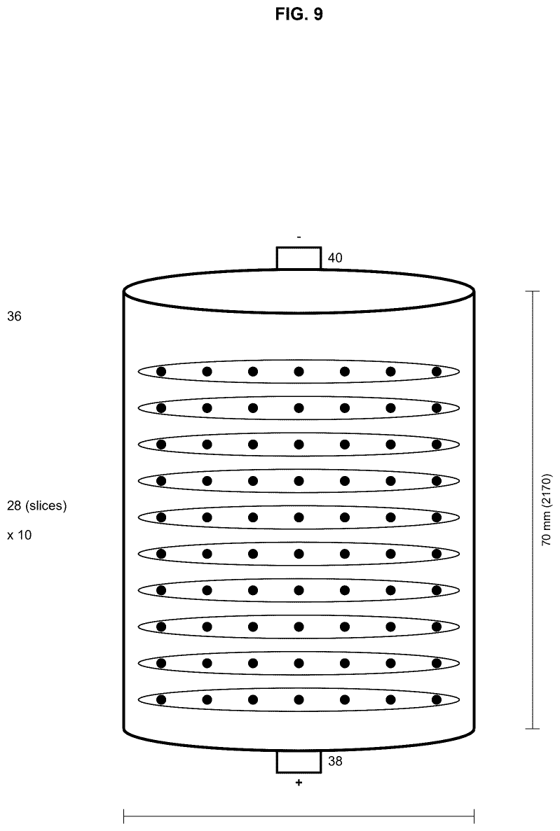

FIG. 10 is an electrical schematic showing series and parallel connection configurations of spherical cells within slices and slices within stacks, including output terminal designations.

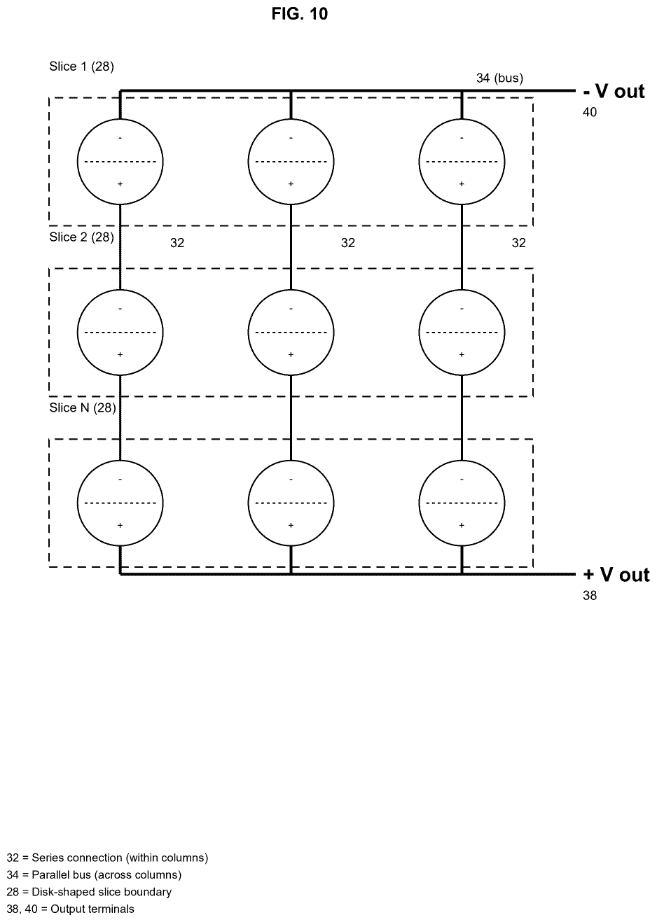

### DETAILED DESCRIPTION OF THE INVENTION

### Overview

The present invention provides a hierarchical nuclear voltaic power source architecture comprising three levels of assembly: (1) individual spherical nuclear voltaic cells, (2) disk-shaped slices containing multiple cells in a planar arrangement, and (3) cylindrical stacks of multiple slices conforming to industry-standard battery form factors. This modular approach enables scalable power output with customizable voltage and current characteristics.

### Spherical Cell Design

The core component of the invention is the spherical nuclear voltaic cell. Each cell is designed to maximize energy conversion efficiency from radioactive decay to electricity through its spherical geometry, which provides uniform radiation distribution and near-complete solid angle coverage. The cell comprises several key functional layers described in the following paragraphs.

### Radioisotopes

The system utilizes at least one of the following radioisotopes, either singly or in combination, for generating ionizing radiation, including but not limited to: P-32, V-48, Cf-253, Cr-51, Md-258, Be-7, Cf-254, Co-56, Sc-46, S-35, Tm-168, Fm-257, Tm-170, Po-210, Ca-45, Au-195, Zn-65, Co-57, V-49, Cf-248, Ru-106, Np-235, Cd-109, Tm-171, Cs-134, Na-22, Fe-55, Rh-101, Co-60, Kr-85, H-3, Cf-250, Nb-93m, Sr-90, Cm-243, Cs-137, Ti-44, U-232, Pu-238, Sm-151, Ni-63, Si-32, Ar-39, Cf-249, Ag-108, Am-241, AmBe, Hg-194, Nb-91, Cf-251, Ho-166m1, Bk-247, Ra-226, Mo-93, Ho-153, Cm-246, C-14, Pu-240, Th-229, Am-243, Cm-244, Cm-245, Cm-250, Nb-94, Pu-239, U-233, U-234, Pu-242, Np-237, U-235, U-236, and U-238. The selection of radioisotope is determined by the target application requirements including desired half-life, emission type (alpha, beta, or gamma), emission energy, specific activity, and regulatory classification.

Preferred radioisotopes for long-duration applications include Ni-63 (half-life 100.1 years, beta emitter), Am-241 (half-life 432.2 years, alpha emitter), Pu-238 (half-life 87.7 years, alpha emitter), and C-14 (half-life 5,730 years, beta emitter). For higher power density applications, Sr-90 (half-life 28.8 years, beta emitter), Cs-137 (half-life 30.2 years, beta/gamma emitter), and Co-60 (half-life 5.27 years, beta/gamma emitter) are preferred.

### Converting Medium

The system utilizes at least one converting medium to contain and interact with the radioisotope emissions and to convert the emitted radiation energy into electricity. The converting medium may comprise solid transducers, liquid transducers, or combinations thereof.

### Solid Transducers—Wide Bandgap Semiconductors

The system utilizes at least one wide bandgap semiconductor converter wherein emitted radiation or photons are captured by high-bandgap materials that efficiently convert them into electrical charges through electron-hole pair generation. The wide bandgap semiconductor materials include, but are not limited to:

| Semiconductor | Bandgap (eV) |
|---|---|
| Silicon Carbide (SiC) | 3.26 |
| Zinc Oxide (ZnO) | 3.37 |
| Gallium Nitride (GaN) | 3.4 |
| Gallium Oxide (Ga2O3) | 4.8 |
| Diamond | 5.5 |
| Boron Nitride (BN) | 5.8 |
| Aluminum Nitride (AlN) | 6.2 |

The semiconductor layers within each spherical cell form p-n junctions. The P-region, doped with acceptor atoms, facilitates the movement of holes when exposed to radiation. The N-region, doped with donor atoms, generates electrons when irradiated. The interaction between the P and N regions forms the basis of the cell's voltaic properties, creating a built-in electric field that separates radiation-generated charge carriers.

### Liquid Transducers

Alternatively or additionally, the system utilizes at least one liquid transducer medium to contain radioisotopes and convert emitted high-energy radiation into electricity. Liquid transducers include liquid semiconductors, liquid scintillators, liquid metals, and ionic liquids.

### Liquid Semiconductors

Liquid semiconductors convert radiation energy directly into electron-hole pairs. These semiconductors may be of either N-type or P-type, depending on the doping elements. The generated charges are extracted through ohmic contacts or electrolytic systems. The liquid semiconductor is contained within a corrosion-resistant structure such as silicon or glass.

Preferred liquid semiconductor materials include:

| | | Density | M.P. | | |
|---|---|---|---|---|---|
| Compound | Formula | (g/cm3) | (C.) | Bandgap (eV) | Type |
| Selenium- | SeI2 | 5.24 | 57 | 1.41 | Semiconductor |
| Iodide | | | | | |
| Selenium- | SeS | 4.39 | 105 | 2.0-2.8 | Semiconductor |
| Sulfur | | | | | |
| Copper | Cu2Se | 6.84 | 1113 | ~2.2 | Semiconductor |
| Selenide | | | | | |
| Germanium | GeSe | 5.12 | 667 | 0.897 | Semiconductor |
| Selenide | | | | | |
| Indium | InSe | 5.39 | 611 | 1.076 | Semiconductor |
| Selenide | | | | | |
| Vanadium | V2O5 | 3.357 | 690 | 2.3 | Semiconductor |
| Pentoxide | | | | | |

The Selenium-Iodide mixture is a preferred liquid semiconductor due to its low melting point of 57 degrees Celsius, enabling liquid-state operation near ambient temperature while maintaining semiconducting behavior suitable for radiation energy conversion.

### Liquid Scintillators

Liquid scintillators convert radiation energy into photons through scintillation. When nuclear radiation interacts with the scintillator material, it excites atoms or molecules which emit photons upon returning to ground state. These photons are then captured by wide bandgap semiconductors positioned adjacent to the scintillator and converted into electrical energy.

Liquid noble gas scintillators include:

| | Scint. | | | | | |
|---|---|---|---|---|---|---|
| | Yield | Emission | Decay | | Ionization | Density |
| Medium | (ph/keV) | (nm) | Time | | (e−/keV) | (kg/m3) |
| Liquid Xenon | 46 | 175 | 3/27 | ns | 64 | 2942 |
| Liquid Krypton | 25 | 148 | 7 | ns | 49 | 2416.7 |
| Liquid Argon | 40 | 128 | 10 ns/ | | 42 | 1395.4 |
| | | | 1.5 us | | | |
| Liquid Neon | 7 | 78 | Few ns/ | | 46 | 1207 |
| | | | 15.4 us | | | |
| Liquid Helium | 15 | 80 | 20 | ns | 39 | 124.74 |

Organic liquid scintillators include pseudocumene (PC)+PPO, linear alkylbenzene (LAB)+PPO, toluene+PPO, xylene+PPO, and phenylxylylethane (PXE)+PPO, each providing scintillation yields of 8-14 photons/keV with emission wavelengths in the 365-430 nm range.

### Liquid Metals

Liquid metals are highly conductive materials that interact directly with radiation to convert kinetic energy into free electrons collected to generate electrical current. Suitable liquid metals include:

| | M.P. | Conductivity | Mobility | Ionization |
|---|---|---|---|---|
| Metal | (C.) | (S/m) | (cm2/Vs) | (e−/keV) |
| Gallium (Ga) | 29.8 | 3.7 × 10\hat{ }6 | 200 | ~15-20 |
| Indium (In) | 156.6 | 1.2 × 10\hat{ }6 | 35 | ~10-15 |
| Tin (Sn) | 231.9 | 9.1 × 10\hat{ }6 | 260 | ~20-25 |
| Bismuth (Bi) | 271.4 | 7.7 × 10\hat{ }5 | 140 | ~25-30 |
| Lead (Pb) | 327.5 | 4.8 × 10\hat{ }6 | 25 | ~20-25 |

Liquid gallium is particularly preferred due to its low melting point of 29.8 degrees Celsius, enabling liquid-state operation at near-ambient temperature. Gallium uniquely allows electrons and Ga+ ions to coexist without immediate recombination, facilitating efficient charge extraction.

### Ionic Liquids

Ionic liquids consist entirely of mobile ions and are liquid at relatively low temperatures. When exposed to radiation, additional ionization increases ionic conductivity. The system applies a potential difference across the ionic liquid to collect and separate the generated charges, directly converting radiation energy into electrical energy.

Suitable ionic liquids include 1-Butyl-3-methylimidazolium bis(trifluoromethylsulfonyl)imide ([BMIM][Tf2N]), 1-Ethyl-3-methylimidazolium tetrafluoroborate ([EMIM][BF4]), 1-Hexyl-3-methylimidazolium hexafluorophosphate ([HMIM][PF6]), and 1-Butyl-1-methylpyrrolidinium bis(trifluoromethylsulfonyl)imide ([BMPy][Tf2N]). Ionic liquids are characterized by low volatility, high thermal stability, high ionic conductivity, and non-flammability, making them suitable for extended-duration nuclear voltaic operation.

### Electrical Contacts

The system utilizes electrical contacts to collect and extract electrical charges generated within the converting medium. Cylindrical contacts connect the P and N regions to the external circuit, allowing cells to be linked in parallel or series with minimized resistance and efficient current flow.

Schottky diode contacts form a metal-semiconductor junction with low forward voltage drop and fast switching. Suitable Schottky contact metals include:

| Schottky Contact | Work Function (eV) |
|---|---|
| Aluminum (Al) | 4.28 |
| Titanium (Ti) | 4.33 |
| Gold (Au) | 5.1 |
| Nickel (Ni) | 5.15 |
| Palladium (Pd) | 5.6 |
| Platinum (Pt) | 5.65 |

Ohmic contacts ensure minimal resistance at the metal-semiconductor interface with linear I-V characteristic. Suitable ohmic contact metals include Gold (Au), Titanium (Ti), Nickel (Ni), Aluminum (Al), Silver (Ag), and Copper (Cu). Other specialized electrical contacts include Indium Tin Oxide (ITO), Graphene, Molybdenum (Mo), Tungsten (W), and Chromium (Cr).

### Encapsulating Layer

Each spherical cell includes an encapsulating layer serving as a protective barrier ensuring structural integrity and shielding the radioactive material from external interference. The encapsulating material is selected for durability, radiation resistance, and ability to contain radiation safely while allowing emitted radiation to pass through to the converting medium.

### Spherical Cell Assembly Configuration

Each spherical cell comprises an inner semiconductor (or converting medium) sphere enclosed by an outer semiconductor (or converting medium) sphere, with a gap between them containing the radioactive material. The inner sphere has a smaller diameter than the outer sphere, creating an intervening space for radioisotope containment. The radioactive material may be in solid, liquid, gaseous, or aerosolized form.

Cylindrical electrical contacts penetrate the spherical cell to connect the P and N regions of both inner and outer semiconductors to external terminals. The top cylindrical contact connects to the negative cell terminal by linking the N-region of the outer semiconductor to the N-region of the inner semiconductor through an extended cylindrical geometry. The bottom cylindrical contact connects to the positive cell terminal by similarly linking the P-regions of both semiconductors.

The outer semiconductor layers comprise, from outside to inside, the encapsulating layer, the P-region layer, and the N-region layer. The inner semiconductor layers comprise the inner substrate, the P-region layer, and the N-region layer. Each layer has a thickness of approximately 0.01 mm, though this may be varied depending on the radioisotope emission energy and the semiconductor material properties.

### Disk-Shaped Slice Assembly

A slice is formed by arranging multiple spherical cells in a planar, disk-shaped configuration. The assembly of cells into a slice is designed to optimize space utilization and ensure consistent radiation exposure across all cells. Within a slice, cells can be connected in either parallel or series configuration.

Parallel connection increases the current output while maintaining consistent voltage, suitable for applications requiring higher current. Series connection increases the voltage output while maintaining consistent current, ideal for applications requiring higher voltage. The number of cells within each slice can be adjusted to meet specific energy and power requirements.

In a preferred embodiment, seven cells per slice are arranged in a close-packed hexagonal configuration, providing optimal packing density. The clustering arrangement enables closer-packed cells that optimize the slice diameter while maintaining sufficient clearance for electrical interconnection and thermal management.

### Cylindrical Stack Configuration

Slices are further stacked into a cylindrical configuration conforming to industry-standard battery form factors. The cylindrical assembly provides several advantages: the number of slices in the stack can be varied to customize energy capacity and power output; the cylindrical design allows for efficient heat dissipation critical for maintaining performance and longevity; slices within the stack can be connected in parallel or series to achieve desired electrical characteristics; and adherence to standard battery geometries ensures compatibility with existing technologies and infrastructure.

The preferred cylindrical form factor is the 2170 standard (21 mm diameter, 70 mm length), widely used in electric vehicle battery packs and energy storage systems. Other compatible form factors include 18650 (18 mm×65 mm), 21700 (21 mm×70 mm), 4680 (46 mm×80 mm), 26650 (26 mm×65 mm), and 32650 (32 mm×65 mm). The modular architecture permits scaling to any cylindrical dimension.

For the 2170 form factor, a preferred configuration comprises 7 spherical cells per slice with approximately 8-12 slices per stack, providing a total of 56-84 individual nuclear voltaic cells within a single 2170-format battery. The specific number of slices is determined by the desired energy capacity and the diameter of the individual spherical cells.

### External Casing

The system utilizes at least one external casing that encompasses the spherical cells and the stacked disk-shaped slices. The casing structure is crucial for maintaining the integrity and safety of the nuclear voltaic power source. The casing provides radiation shielding compliant with applicable regulations, structural protection, and standard battery terminal interfaces.

The external casing materials must possess high mechanical strength, radiation resistance, and compatibility with the converting medium and semiconductor converter. Suitable materials include:

| Material | Tensile Strength (MPa) | Density (g/cm3) |
|---|---|---|
| Inconel 617 | 769 | 8.19 |
| SIFSIX-3-Cu | 70 | 1.168 |
| Ni-MOF-74 | 70 | 1.174 |
| MOF-505 | 90 | 1.172 |
| Stainless Steel 304 | 515-625 | 7.93 |
| Stainless Steel 316 | 579 | 8.0 |
| GH3535 | 308-360 | 8.05 |
| Silicon | 48-97 | 2.329 |
| Glass (Annealed) | 32-78 | 2.5 |
| Glass (Heat-Strengthened) | 70-140 | 2.5 |

### Electrical Interconnection Architecture

The hierarchical electrical interconnection architecture provides three levels of configurability. At the cell level, each spherical cell generates a voltage determined by the semiconductor bandgap and converting medium properties. At the slice level, cells are connected in parallel (for increased current at constant voltage) or in series (for increased voltage at constant current). At the stack level, slices are connected in parallel or series to produce the desired aggregate output.

For a 2170-format assembly with 7 cells per slice and 10 slices, exemplary configurations include: (a) all cells in parallel within each slice, all slices in series, producing N times single-cell voltage at 7 times single-cell current where N is the number of slices; (b) all cells in series within each slice, all slices in parallel, producing 7 times single-cell voltage at N times single-cell current; (c) mixed configurations with some slices in series and some in parallel to achieve intermediate voltage and current characteristics.

The interconnection topology is established during assembly by the routing of conductive pathways between cell terminals, slice bus bars, and stack output terminals. This enables a single manufacturing process to produce batteries with different electrical specifications by varying only the interconnection pattern.

### Thermal Management

The cylindrical form factor facilitates efficient thermal management through radial heat dissipation from the central axis to the external casing surface. For liquid transducer embodiments, the temperature must be maintained within the liquid-phase operating range of the selected transducer material. The external casing may incorporate thermally conductive pathways, phase-change materials, or active cooling interfaces compatible with existing battery thermal management systems.

### Applications

The nuclear voltaic power source of the present invention is suitable for a wide range of applications including but not limited to: space exploration missions requiring power sources lasting decades; medical implants including cardiac pacemakers and neurostimulators; military and defense applications including unattended sensors and communication equipment; deep-sea exploration and monitoring equipment; Internet of Things (IoT) sensor networks in remote or inaccessible locations; emergency and disaster response infrastructure; electric vehicle range extenders providing continuous trickle-charge; and grid-scale energy storage buffer systems.

The compatibility with industry-standard battery form factors enables direct integration into existing battery packs designed for lithium-ion cells, leveraging established battery management system architectures, charging connectors, and form factor specifications.

### Specific Embodiments

In a first embodiment, a 2170-format nuclear voltaic battery comprises 7 spherical SiC semiconductor cells per slice with 10 slices stacked vertically. Each cell utilizes Ni-63 as the beta-emitting radioisotope in solid form between inner and outer semiconductor spheres. The cells within each slice are connected in parallel, and the slices are connected in series. The external casing is Stainless Steel 316 with standard 2170 positive and negative terminals. This embodiment is optimized for long-duration, moderate-power applications.

In a second embodiment, a 4680-format nuclear voltaic battery comprises 19 spherical cells per slice in a close-packed arrangement with 12 slices stacked vertically. Each cell utilizes a liquid xenon scintillator converting medium with Am-241 alpha-emitting radioisotope and diamond wide bandgap semiconductor for photon-to-electrical conversion. The external casing is Inconel 617. This embodiment is optimized for high-power automotive applications.

In a third embodiment, an 18650-format nuclear voltaic battery comprises 4 spherical cells per slice with 8 slices stacked vertically. Each cell utilizes liquid gallium as the converting medium with Sr-90 beta-emitting radioisotope. The cells are connected in a series-parallel hybrid configuration. The external casing is GH3535 alloy. This embodiment is optimized for portable electronics.

In a fourth embodiment, a 2170-format nuclear voltaic battery comprises 7 spherical cells per slice utilizing ionic liquid ([BMIM][Tf2N]) converting medium with Cs-137 radioisotope. An applied potential difference across the ionic liquid facilitates charge separation and collection. The external casing is Stainless Steel 304. This embodiment is optimized for remote IoT sensor applications.

### Fabrication Methods

The spherical cells are fabricated by: (a) forming the inner semiconductor sphere through deposition of semiconductor material on a spherical substrate followed by doping to create p-n junctions; (b) applying encapsulating material to the inner sphere exterior; (c) forming the outer semiconductor sphere as two half-shells; (d) positioning the inner sphere within the outer half-shells; (e) installing cylindrical electrical contacts through designated passages in the outer sphere; (f) sealing the outer sphere around the inner sphere to create the radioisotope-containing gap; (g) introducing the radioisotope material through a fill port; and (h) sealing the fill port.

Disk-shaped slices are assembled by: (a) arranging the desired number of spherical cells in the close-packed planar configuration; (b) establishing electrical connections between cell terminals according to the desired series or parallel topology; (c) securing cells in position within a slice frame or potting material.

Cylindrical stacks are assembled by: (a) stacking the desired number of slices vertically; (b) establishing inter-slice electrical connections; (c) inserting the stack into the external casing; (d) connecting the stack output terminals to the casing terminals; (e) sealing the external casing to provide radiation containment compliant with 10 CFR Part 20 or equivalent national regulations.

What is claimed is:

1. A nuclear voltaic power source comprising:
a plurality of spherical nuclear voltaic cells, each cell comprising: at least one radioisotope selected from a group of alpha, beta, and gamma emitters; at least one converting medium disposed in proximity to the radioisotope for converting radiation energy into electrical energy; at least one pair of electrical contacts for extracting generated electrical charges; and an encapsulating layer surrounding the cell;
wherein the plurality of spherical cells are arranged in at least one disk-shaped slice in a planar configuration; and
wherein the at least one disk-shaped slice is disposed within a cylindrical external casing conforming to an industry-standard battery form factor.

2. The nuclear voltaic power source of claim 1, wherein the industry-standard battery form factor is selected from the group consisting of: 2170 format having approximately 21 mm diameter and 70 mm length; 18650 format having approximately 18 mm diameter and 65 mm length; 21700 format having approximately 21 mm diameter and 70 mm length; 4680 format having approximately 46 mm diameter and 80 mm length; and 26650 format having approximately 26 mm diameter and 65 mm length.

3. The nuclear voltaic power source of claim 1, wherein the converting medium comprises at least one wide bandgap semiconductor selected from the group consisting of Silicon Carbide (SiC), Zinc Oxide (ZnO), Gallium Nitride (GaN), Gallium Oxide (Ga2O3), Diamond, Boron Nitride (BN), and Aluminum Nitride (AlN), the semiconductor forming a p-n junction within the spherical cell geometry.

4. The nuclear voltaic power source of claim 1, wherein the converting medium comprises at least one liquid transducer selected from the group consisting of liquid semiconductors, liquid scintillators, liquid metals, and ionic liquids.

5. The nuclear voltaic power source of claim 4, wherein the liquid transducer comprises a liquid semiconductor including a Selenium-Iodide mixture.

6. The nuclear voltaic power source of claim 4, wherein the liquid transducer comprises at least one liquid noble gas scintillator selected from the group consisting of Liquid Xenon, Liquid Krypton, Liquid Argon, Liquid Neon, and Liquid Helium, disposed in combination with at least one wide bandgap semiconductor for converting scintillation photons into electrical energy.

7. The nuclear voltaic power source of claim 4, wherein the liquid transducer comprises liquid gallium.

8. The nuclear voltaic power source of claim 1, wherein each spherical cell comprises an inner semiconductor sphere and an outer semiconductor sphere with the radioisotope disposed in an intervening space between the inner and outer spheres.

9. The nuclear voltaic power source of claim 1, wherein the spherical cells within each disk-shaped slice are connected in at least one of a parallel configuration and a series configuration.

10. The nuclear voltaic power source of claim 1, wherein the electrical contacts comprise cylindrical contacts penetrating the spherical cell, connecting P-type and N-type semiconductor regions of inner and outer semiconductor spheres to positive and negative cell terminals respectively.

11. A cylindrical nuclear voltaic battery assembly comprising:
an external casing having dimensions conforming to an industry-standard cylindrical battery form factor;
a plurality of disk-shaped slices disposed within the external casing in a stacked arrangement along a longitudinal axis of the external casing, each slice comprising a plurality of spherical nuclear voltaic cells arranged in a planar configuration;
wherein each spherical nuclear voltaic cell comprises at least one radioisotope, at least one converting medium, and at least one pair of electrical contacts;
an electrical interconnection arrangement connecting the plurality of spherical cells within each slice and connecting the plurality of slices within the stack; and
positive and negative output terminals disposed on the external casing compatible with standard battery terminal specifications.

12. The cylindrical nuclear voltaic battery assembly of claim 11, wherein the external casing conforms to the 2170 cylindrical battery format having approximately 21 mm diameter and 70 mm length.

13. The cylindrical nuclear voltaic battery assembly of claim 11, wherein the external casing conforms to the 4680 cylindrical battery format having approximately 46 mm diameter and 80 mm length.

14. The cylindrical nuclear voltaic battery assembly of claim 11, wherein each disk-shaped slice comprises at least seven spherical cells arranged in a close-packed hexagonal configuration.

15. The cylindrical nuclear voltaic battery assembly of claim 11, wherein the electrical interconnection arrangement provides selectively configurable series and parallel connections among the spherical cells within each slice and among the slices within the stack.

16. The cylindrical nuclear voltaic battery assembly of claim 11, wherein the external casing comprises a material selected from the group consisting of Inconel 617, Stainless Steel 304, Stainless Steel 316, GH3535, SIFSIX-3-Cu, Ni-MOF-74, and MOF-505, the external casing providing radiation shielding in compliance with applicable regulatory requirements.

17. The cylindrical nuclear voltaic battery assembly of claim 11, wherein the converting medium of at least one spherical cell comprises a solid transducer including a wide bandgap semiconductor, and the converting medium of at least one other spherical cell comprises a liquid transducer.

18. The cylindrical nuclear voltaic battery assembly of claim 11, further comprising thermal management provisions including at least one of thermally conductive pathways between the slices and the external casing, phase-change materials, and active cooling interfaces.

19. A method of manufacturing a nuclear voltaic battery in a standard cylindrical battery form factor, the method comprising:
fabricating a plurality of spherical nuclear voltaic cells, each cell comprising at least one radioisotope, at least one converting medium, and at least one pair of electrical contacts;
arranging a first subset of the spherical cells in a planar configuration to form a first disk-shaped slice;
arranging a second subset of the spherical cells in a planar configuration to form a second disk-shaped slice;
establishing electrical connections among the spherical cells within each slice according to a desired parallel or series connection topology;
stacking the first and second disk-shaped slices along a longitudinal axis;
establishing electrical connections between the first and second disk-shaped slices; and
disposing the stacked slices within a cylindrical external casing conforming to an industry-standard battery form factor, the external casing including positive and negative output terminals.

20. The method of claim 19, wherein the industry-standard battery form factor is selected from the group consisting of the 2170, 18650, 21700, 4680, and 26650 cylindrical battery standards.

21. The method of claim 19, further comprising: fabricating additional disk-shaped slices from additional subsets of spherical cells; and stacking a total of 3 to 20 disk-shaped slices within the external casing.

22. The method of claim 19, wherein arranging the spherical cells in a planar configuration comprises arranging at least seven spherical cells in a close-packed hexagonal pattern.

23. The method of claim 19, wherein establishing electrical connections among the spherical cells within each slice comprises connecting each cell in parallel for increased current output.

24. The method of claim 19, wherein establishing electrical connections between the slices comprises connecting the slices in series for increased voltage output.

25. The method of claim 19, further comprising sealing the external casing to provide radiation containment in compliance with regulatory requirements.

26. A scalable nuclear voltaic power system comprising:
at least two cylindrical nuclear voltaic battery units, each unit comprising: a cylindrical external casing conforming to an industry-standard battery form factor; a plurality of disk-shaped slices stacked within the external casing, each slice comprising a plurality of spherical nuclear voltaic cells; and output terminals on the external casing; and
an interconnection arrangement connecting the at least two cylindrical nuclear voltaic battery units in at least one of a series configuration and a parallel configuration.

27. The scalable nuclear voltaic power system of claim 26, wherein each cylindrical nuclear voltaic battery unit conforms to the 2170 battery form factor and is compatible with battery management systems designed for lithium-ion 2170 cells.

28. The scalable nuclear voltaic power system of claim 26, wherein the spherical nuclear voltaic cells in a first battery unit comprise a solid semiconductor converting medium and the spherical nuclear voltaic cells in a second battery unit comprise a liquid transducer converting medium.

29. The scalable nuclear voltaic power system of claim 26, wherein the at least two cylindrical nuclear voltaic battery units are arranged in a battery pack configuration compatible with electric vehicle battery module specifications.

30. The scalable nuclear voltaic power system of claim 26, further comprising a battery management system configured to monitor and control the output of the at least two cylindrical nuclear voltaic battery units.
